(19) United States
(12) Patent Application Publication
(10) Pub. No.: US 2009/0140388 A1
(43) Pub. Date: Jun. 4, 2009

(54) INTEGRATED CIRCUIT INCLUDING AN EMITTER STRUCTURE AND METHOD FOR PRODUCING THE SAME

(75) Inventors: Joachim Joos, Emmering (DE); Matthias Stecher, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies Austria AG, Villach (AT)

(21) Appl. No.: 11/947,246

(22) Filed: Nov. 29, 2007

(51) Int. Cl. H01L 29/732; H01L 21/331

(52) U.S. Cl. 257/580; 438/342; 257/E29.183; 257/E21.375

(57) ABSTRACT

A semiconductor emitter structure for emitting charge carriers of a first conductivity type in a base volume of a second conductivity type material neighbored to the emitter structure in a vertical direction, includes multiple emitter volumes of first conductivity tape material having a predetermined lateral dimension in a lateral direction perpendicular to the vertical direction. The emitter volumes are, in the lateral direction, neighbored by semiconductor volumes of second conductivity type material, wherein the predetermined lateral dimension is such that space charges created by second conductivity type carriers laterally diffusing into the emitter volumes from the semiconductor volumes limit a maximum density of first conductivity type carriers within the emitter volumes by more than 20% as compared to emitter volumes of the same lateral dimension not neighbored by semiconductor volumes of the second conductivity type material.

### BACKGROUND

Multiple semiconductor devices are known, which use emitter structures to emit charge carriers into semiconductor areas or volumes which are neighbored to the emitter structure.

For example, bipolar transistors comprise an emitter-volume, a base-volume, and a collector-volume of semiconductor material with alternating dopants. The emitter structure often has a high concentration of dopants, such as to provide charge carriers with high efficiency. Further examples for devices having an emitter structure are Electrostatic Discharge (“ESD”)-protection devices, used to protect electronic equipment, when an electrostatic discharge occurs. To this end, the charge provided by the electrostatic discharge event is transferred via the ESD-device, rather than via the protected device, which could eventually be destroyed by the high current produced by the deposited charge.

ESD-protection devices are designed to operate at a predetermined threshold voltage, i.e. when the threshold voltage is exceeded, the ESD-protection device typically connected in parallel to the protected device, becomes conductive with a relatively low resistance, such as to transport the current and prevent it from flowing through the protected device. Such, an ESD-protection device could be compared with a thyristor, which starts conducting at a predetermined threshold voltage. However, ESD-devices stop conducting when the voltage drops below a switch-off voltage, which depends on the specific design of the ESD-protection device. In some of the devices, the switch-off-voltage is significantly lower than the threshold voltage of the device.

### SUMMARY

Some embodiments discussed in further detail below comprise an emitter structure for emitting charge carriers of a first conductivity type. The emitter structure may emit the charge carriers in a vertical direction and comprise emitter volumes of first conductivity type material as well as semiconductor volumes of second conductivity type material, which neighbor the emitter volumes in a lateral direction perpendicular to the vertical direction. In some embodiments, the lateral dimension in the lateral direction of the emitter volume may be chosen such that an emitter efficiency with which charge carriers are emitted from the emitter volume is, in a predictable manner, limited for high currents. This may be the case, when the lateral dimension is chosen such that space charges created within the emitter volume by lateral diffusion of second conductivity type carriers from the neighboring semiconductor volumes limit a maximum charge carrier density of first conductivity type carriers within the emitter volume by more than 20% as compared to identical emitter volume not being neighbored by a semiconductor volume of the second conductivity type.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

Several embodiments will in the following be discussed referencing the enclosed figures, wherein:

FIG. 1 illustrates an embodiment of an emitter structure.

FIG. 2 illustrates an example for a charge transmission probability of an embodiment of an emitter structure.

FIG. 3A and 3B illustrate an embodiment of an ESD-protection device.

FIG. 4 illustrates a current—voltage dependency of the ESD-device of FIG. 3.

FIG. 5A and 5B illustrate a further embodiment of an ESD-protection device.

FIG. 6 illustrates a current—voltage dependency of the ESD-device of FIG. 5.

FIG. 7 illustrates an embodiment of a method for creating an emitter structure.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

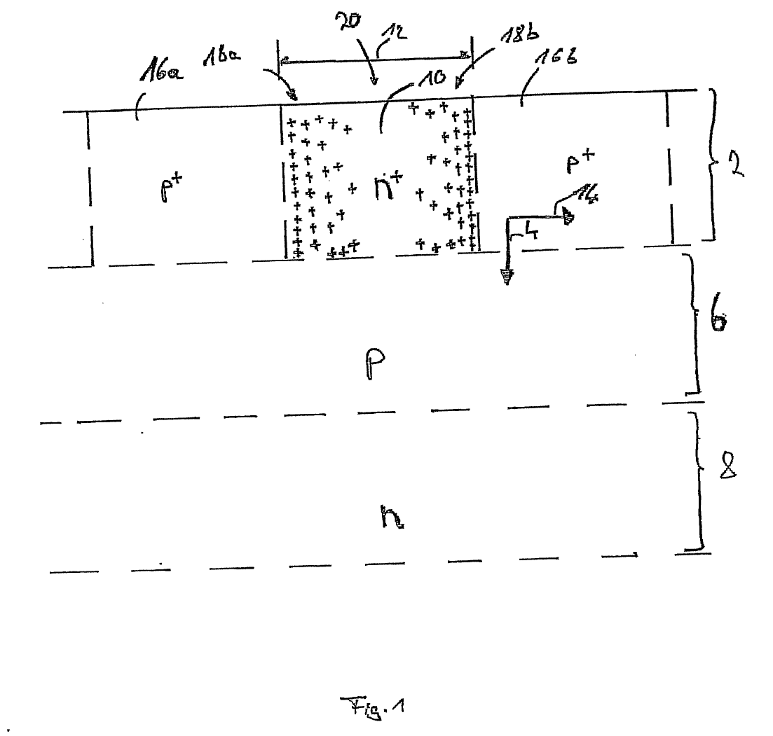

Embodiments of the invention may be implemented, for example, partially integrated circuits or fully integrated circuits. FIG. 1 illustrates a 2-dimensional projection of a 3-dimensional embodiment of an emitter structure 2 used, as an implementation example, within a npn bipolar-transistor. That is, the emitter structure, which is intended to emit charge carriers in a vertical direction 4, is, in the vertical direction, neighbored to a base volume 6, which is again neighbored to a collector volume 8. The emitter structure is intended to emit charge carriers of a first charge carrier type. Therefore, the base volume 6 is formed by material of a second conductivity type and the collector volume 8 is of the first conductivity type. In this particular example, the first conductivity type is chosen to be electrons, i.e. the emitter is intended to emit electrons into a p-doped base volume 6. The emitter structure 2 includes an emitter volume 10 of first conductivity type material, which is of predetermined lateral dimension 12 in a lateral direction 14, wherein the lateral direction 14 is perpendicular to the vertical direction. The emitter volume 10 is, in the lateral direction, neighbored by semiconductor volumes 16a and 16b of second conductivity type material.

According to some embodiments, the lateral dimension is appropriately chosen to match a predetermined lateral dimension for the reasons set forth below. Charge carriers of the second conductivity type diffuse (using the electron-hole-model) laterally into the emitter volume 10, such that space charge regions 18a and 18b are created at the borders to the semiconductor volumes 16a and 16b of the second conductivity type material. The extension of the space charge regions in the lateral dimension depends also on the dopant concentration of the emitter volume 10 and the semiconductor volumes 16a and 16b. By a variation of the lateral dimension 12, the volume or area 20 within the emitter volume 10, which is not populated by space charges, may be varied. That is, making the lateral dimension 12 bigger, the unpopulated area would increase, i.e. a region 20 between the space charge volumes 18a and 18b will become wider. By choosing the lateral dimension 12, the charge transport properties of the emitter volume 10 may be varied as detailed below. This effect may also be seen as a variation of the emitter efficiency of an npn-transistor formed using the emitter structure 2, the base volume 6 and the collector volume 8.

For the following considerations, the structure in FIG. 1 shall be assumed to be connected to external voltages such that the bipolar transistor is switched on. That is, electrons are emitted from the emitter volume 10 into the base volume 6. The emission is, however, affected by the space charge areas 18a and 18b.

Assuming there are no space charge areas 18a and 18b present, electrons are emitted from the emitter volume 10 into the base volume 6, from where they are transferred to the collector volume 8. This situation may be compared to the conditions within the central area 20 of the emitter volume 10, where no space charges are present.

However, electrons intended to travel in the vertical direction within the space-charge areas 18a and 18b have a higher probability of recombining with the space charges, i.e. with the holes causing the space charges in volumes 18a and 18b. When the current density within the emitter volume 10 is low, the generation of the space charge areas 18a and 18b by the semiconductor volumes 16a and 16b is of minor influence to the device performance, as npn-operation can be achieved with the electrons emitted or transported through the central area 20. However, the more the current increases, the more of the emitter volume 10 will be used, i.e. the charge carrier density within the emitter volume 10 increases. That is, in a simple picture, while being operated with relatively low currents, the central volume 20 of the emitter volume 10 is used to transport charge carriers or electrons. The more the current increases, the more area (more of the complete lateral dimension 12) will be used for charge transport. The more area used, the more electrons travel along paths having a high recombination probability, that is pass through areas or volumes of high space charge. The higher the current, the higher the probability that the single electron recombines or is transferred to the laterally neighbored semiconductor volumes 16a or 16b. When discussing a bipolar transistor, the effect could also be described as a dynamical variation of the emitter efficiency of the transistor, caused by the previously described effects.

In other words, the lateral dimension of the emitter volume 12 of the emitter structure of FIG. 1 may be chosen such that the space charges of the second conductivity type, which laterally diffuse into the emitter volume 10, limit a maximum density of first conductivity tape carriers within the emitter volume 10. To quantify the effect, this limiting could be compared to an emitter volume of the same lateral dimension, which is not neighbored by semiconductor volumes of the second conductivity type material. By varying the predetermined lateral dimension of the emitter volume 12, it is principally possible to apply arbitrary limits. For example, when the lateral dimension 12 is chosen to be orders of magnitudes larger than the lateral extension of the space charge regions 18a and 18b (depending on the dopant concentrations of the emitter volume 10 and the semiconductor volumes 16a and 16b), the effect can be negligible such that no measurable limit is applied by the geometrical shape. However, other limits may apply which are due to inherent material properties. That is, for example, a maximum charge carrier concentration still exists, which is the maximum charge carrier concentration of the semiconductor material. However, choosing the lateral dimension appropriately, tighter constraints may be applied.

For example, limiting a maximum density of first conductivity type carriers by more than 20% as compared to an undisturbed emitter volume of the same geometrical shape may be implemented. This may be achieved by choosing the lateral dimension 12 in the regime of microns. Thus, for example, some embodiments may have lateral dimensions smaller than 5 μm, 1 μm or 0.8 μm.

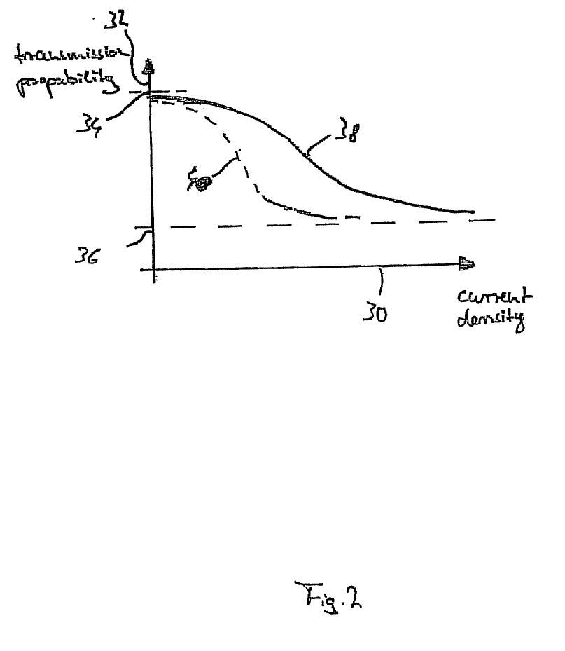

FIG. 2 illustrates examples of transmission probabilities for an electron intended to traverse the emitter volume 10 in the vertical direction, depending on the current density within the emitter volume 10. The current density is plotted on the x-axis 30, whereas the transmission probability of a single electron is plotted on the y-axis 32. It goes without saying that the identical considerations may also be valid for the complementary situation, i.e., having built a p-emitter and negative space charge areas.

At low current densities, the transmission probability is close to an upper threshold value 34, which is close to the equivalent value of an emitter structure having an infinitely extending emitter volume. That is, the value of the threshold is mainly due to the inherent material properties or the dopant profiles of the emitter volume.

If, however, the current density increases, the transmission probability approaches a lower threshold 36, which depends on the extension of the space charge areas into the emitter volume. By varying the lateral dimension 12, the attenuation of the transmission probability may be varied. The solid line 38 may be an example for an emitter structure with a first lateral dimension, the dashed line 40 may be a transmission probability resulting from an emitter structure using similar doping concentrations, but smaller lateral dimensions 12 of the emitter volumes.

To be able to switch a high overall current having emitter volumes of limited lateral dimension, the generation of multiple emitter volumes within an emitter structure may be foreseen, each of the emitter volumes fulfilling the constraint with respect to the lateral dimension. Each of the emitter volumes may be electrically short circuited with each other to form a common terminal area. This may, on the one hand, provide the dynamical variation of the current transport probabilities and, on the other hand, provide the possibility of switching a high overall current.

The adjustment of the charge transport properties may be achieved by a fairly simple modification of the layout, for example, by appropriately designing the geometry of the photo-lithographic masks. This is simpler to be controlled as, for example, the adjustment of dopant profiles within tight tolerances.

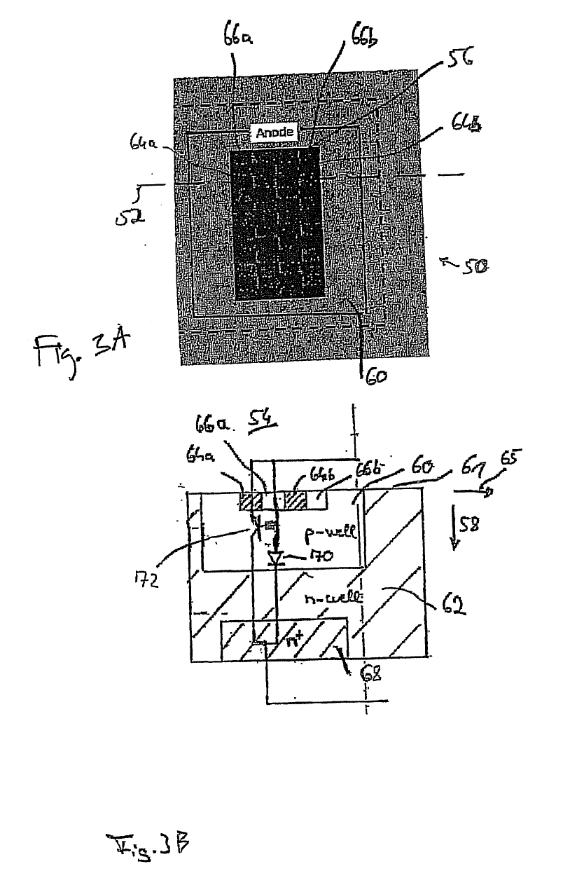

FIG. 3A illustrates an embodiment of a 3-dimensional ESD-protection structure in a face-on illustration 50 of the 3-dimensional structure. Furthermore, in FIG. 3B, a 2-dimensional projection of a section along line 52 illustrates the functionality of the ESD-protection structure. Within those different views, and also within different embodiments subsequently discussed, identical reference numbers are used for identical components or components sharing the same functionality, wherein a repeated description of those components is, for the sake of conciseness, omitted.

The embodiment of an ESD-protection structure 54 includes an emitter structure 56, which is, in a vertical direction 58, neighbored by a base volume 60. In the particular embodiment of FIG. 3, the base volume extends also to a common top surface 61 of the structure, such that the emitter structure 56 is, in any lateral dimension perpendicular to the vertical direction 58, enclosed by the base volume 60.

The base volume is furthermore neighbored, in the vertical direction 58, by a collector volume 62. The emitter structure 56 includes multiple emitter volumes of first conductivity type material, as for example the emitter volumes 64a and 64b, which are n-doped.

In a lateral direction 65 perpendicular to the vertical direction, the emitter volumes are neighbored by semiconductor volumes of second conductivity type material, as for example by semiconductor volumes 66a and 66b. The base volume 60 is made up of second conductivity type material, i.e. of p-doped semiconductor material. The collector volume 62 is made up of n-doped material, i.e. of the first conductivity type material. To provide for a low loss electrical contact, the collector volume 62 furthermore includes a highly doped contact area 68, which could for example, be contacted by a metallization or similar measures.

The semiconductor structure of FIG. 3 may be used as an ESD-protection device when the structure is connected in parallel to a device to be protected. To this end, a cathode terminal may be connected to the collector volume and an anode terminal may be connected to both the emitter volumes 64a and 64b and the semiconductor volume 66a and 66b. To this end, the semiconductor volumes 66a and 66b and the emitter volumes 64a and 64b may, for example, be electrically short circuited to from a common terminal area.

For the explanation of the functionality of the ESD-protection device, several discrete circuit elements are illustrated within the 2-dimensional projection of FIG. 3B, serving as a substitution of the functionality of the respective semiconductor structures. It is, however, noted that only those semiconductor structures or borders are illustrated by circuit elements, which are essential for the understanding of the principle of operation of the ESD-protection structure. A border between the base volume 60 and the collector volume 62 forms, in the vertical direction, a diode 70. The emitter volume 64a, the neighboring base volume 60 and the further neighboring collector volume 62 may be seen as a bipolar transistor 72 formed in the vertical direction 58. For example, one part of the transistor uses emitter volume 64a as an emitter, another part uses emitter volume 64b. The multiple individual semiconductor volumes 66a and 66b, which are of high p-dopant concentration, may be understood as contact areas providing the possibility of contacting the base volume and thus, the diode 70.

The fact that the emitter volumes 64a and 64b are, in the lateral direction, neighbored by the semiconductor volumes 66a and 66b, dynamically limits or alters the charge transport properties of the emitter volumes, as previously described.

The purpose of an ESD-protection device is to efficiently transfer ESD-charges, when a threshold voltage is exceeded. The threshold voltage may be higher than an operating voltage of the device to be protected. Thus, when an electronic discharge occurs, the threshold voltage is exceeded and the ESD-protection device becomes conductive, such that a charge deposited during the ESD event can be transferred to ground.

The ESD-protection structure may be connected to an external circuitry such that the positive potential is applied to the collector volume 62 (via contact area 68). Thus, when the geometrical dimensions of the collector and base volumes are appropriately chosen, the EDS-protection structure of FIG. 3 blocks current flow, when the voltage does not exceed the operation voltage of the protected device.

If, however, the voltage rises due to an ESD-event, an avalanche breakthrough may occur at diode 70, such that current flows through the diode 70. As the substrate itself has an inherent resistance, the rising avalanche current through the substrate causes a voltage gradient or a potential gradient within the structure. The higher the resistivity of the material, the steeper the gradient per unit length. At a certain current flow through the diode 70, the potential difference between the base volume and the emitter volume of the transistor 72 will be as high as to switch the transistor on, such that current is also transported by the transistor structure, i.e., through emitter volumes 64a and 64b. Once the transistor structure 72 is switched on, a resistance of the device decreases, and current is efficiently transported through the structure.

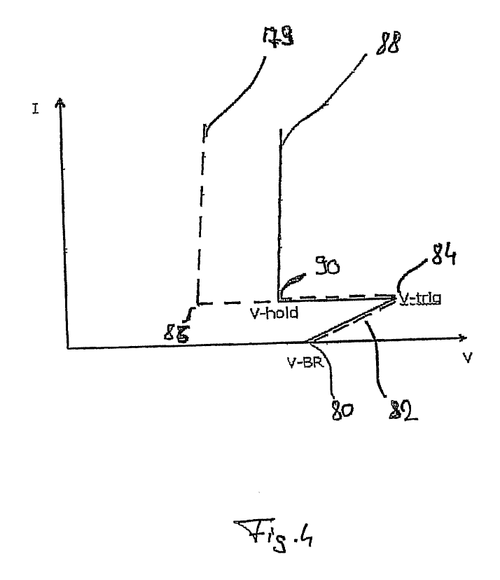

This principle behavior is illustrated by the dashed line of FIG. 4, which illustrates the dependency of the current transported through the device and the voltage at the terminals of an ESD-protection structure 54. The voltage is plotted on the x-axis whereas the current through the device is plotted on the y-axis. At the breakthrough of the diode, namely when the breakthrough or threshold voltage 80 is exceeded, the structure becomes conductive, since diode 70 suffers an avalanche breakthrough. From this very moment, the current may rise within the structure, and in parallel to the current, the voltage rises between the terminals, due to the intrinsic resistance of the semiconductor material. This is illustrated by the linearly increasing section 82 of the I-U-function 79. However, when the potential difference within the device is as high as to trigger the operation of the transistor 72, the transistor becomes conductive. This is, in this particular example, the case at point 84. If, however, the transistor structure 72 becomes conductive, the potential difference between the terminals required to keep the structure “switched on”, decreases to voltage 86. This is the case, since the current may now mainly be transferred through the transistor 72, having a low on-resistance.

Thus, using the structure of FIG. 3, an ESD-protection device may be implemented, being capable of transferring high currents, once an ESD-event has occurred and the threshold-voltage has been exceeded. In particular, a higher current may be transferred, as compared to the use of a protection diode alone, which would suffer from thermal death at much lower currents than the currents which can be handled by the EDS-protection structure of FIG. 3. However, a voltage 86, the “hold-voltage”, required to keep the ESD-protection device conductive significantly below the threshold voltage 80, may impose problems in practical use. If, for example, an operating voltage of the device to be protected is between the hold-voltage 86 and the threshold voltage 80, the voltage supply of the device to be protected will keep the ESD-protection structure 54 conductive, and finally lead to the destruction of the device, provided that the voltage source is capable of delivering high currents.

By geometrically structuring the emitter structure 56 of the ESD-protection device in an appropriate manner, for example by varying the lateral dimension of the emitter volume 64a and 64b, the charge transport efficiency or the charge transfer capability of the emitter volumes 64a and 64b can be adjusted. With embodiments of an ESD-protection device having an emitter structure 56, the hold-voltage may be varied, and in particular, be chosen such that the ESD-protection structure 54 shows the behavior of the solid curve 88, where the hold-voltage 90 is close to the threshold voltage 80. The ESD-protection device may be operative with a characteristic close to the characteristic of a switch. This characteristic may be obtained and the threshold voltage 80 and the hold-voltage 90 may be arbitrarily chosen using an embodiment of the ESD-protection structure of FIG. 3. The threshold voltage, i.e. the breakthrough voltage of the diode 70, and such the switching into the conductive state may be varied by simple layout modifications of the semiconductor structure. Furthermore, the hold-voltage may be chosen by simple geometrical layout variations, such that an ESD-protection device using an emitter structure according to some of the embodiments described herein may be precisely tailored to the actual requirements in a cost efficient and easy to implement manner.

Some embodiments may, for example, be dimensioned such that the threshold voltage is around 50 V, whereas the hold-voltage is 40 V or more. Thus, devices having an operation voltage of somewhat less than 40 V, say for example, 35 V, may be reliably protected. To achieve a hold-voltage close to the trigger voltage, some embodiments may have base volumes, extending in a lateral dimension perpendicular to the vertical direction of the device by no more than 5 μm. Further embodiments may have emitter volumes with a lateral dimension smaller than 1.0 μm, or even as small as 0.8 μm. In further embodiments, the dopant concentrations of the emitter volumes and the semiconductor volumes is greater than 1*10¹⁹ 1/cm³ and smaller than 5*10²¹ 1/cm³. As the previous discussion indicated, the precise geometrical shape in the lateral dimension is of minor concern. It is, instead, a lateral dimension of the emitter volumes which is to be adjusted. The emitter volumes, or, to be more precise, the lateral shape of the emitter volumes of the emitter structure 56, do not necessarily have to be rectangular. For example, the emitter volumes could be also be circular, six-cornered, or of any geometrical shape, provided the lateral dimension is chosen such as to achieve the desired dynamical variation of the efficiency of the emittance of charge carriers into the base volume.

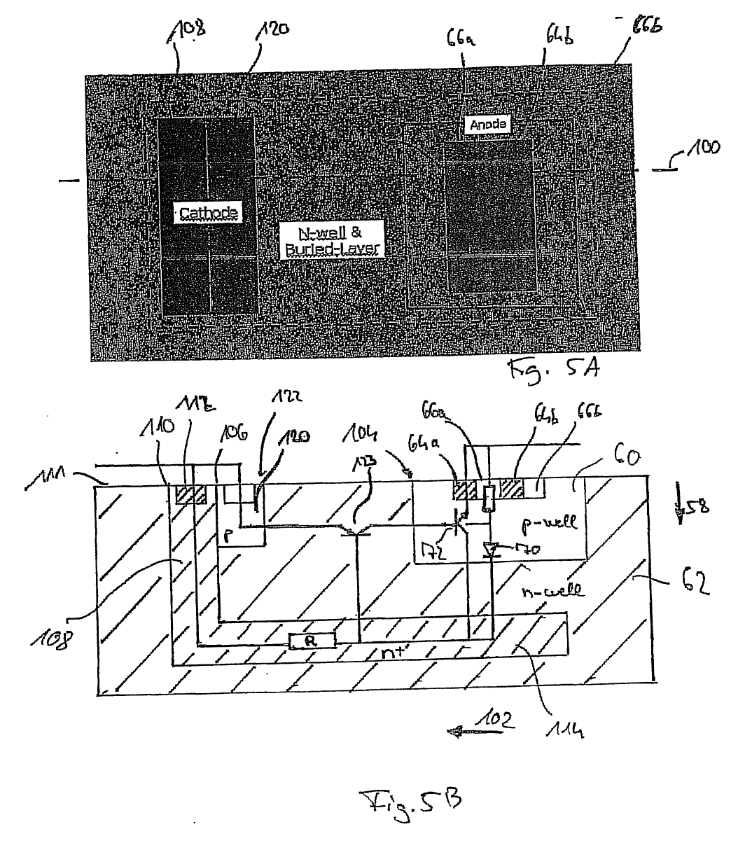

FIGS. 5A and 5B illustrate a further embodiment of an ESD-protection device with two terminals being spaced apart in a lateral direction. That is, the embodiment has additional electrically functional components in a lateral device direction 102, extending perpendicular to the vertical direction 58 of the previously discussed embodiment. As in FIG. 3A, the ESD-protection structure is illustrated in a face on view in FIG. 5A, and in a 2-dimensional projection resulting from a section along line 100 in FIG. 5B. As far as the vertical components are concerned, reference is herewith made to the description of those components within the previous embodiments.

In the embodiment of FIG. 5, the base volume extends in a lateral device direction 102, perpendicular to the vertical direction 58, up to a first semiconductor transition 104, separating the base volume 60 from the collector volume 62. The collector volume 62 extends in the lateral device direction 102 up to a terminal border 106, such that the collector volume 62 laterally extends from the first semiconductor transition 104 to the terminal border 106.

A vertical charge transport volume 108 of first conductivity type material extends, in the lateral device direction 102, from the terminal border 106 to a lateral device border 110. The vertical charge transport volume 108 includes, on a main surface 111 of the ESD-protection structure, a highly doped contact volume 112 of first conductivity type material. The highly doped contact volume 112 is used to electrically contact the vertical charge transport volume 108 using, for example, a metallization. The ESD-protection structure further includes a lateral charge transport volume 114, which is, in the vertical direction 58, neighbored to the collector volume 62 and which extends in the lateral device direction 102 up to the lateral device border 110. As such, the vertical charge transport volume 114 and the lateral charge transport volume 108 form a common volume with a high dopant concentration. This volume is intended to transport the charge carriers transmitted through the vertical components of the ESD-protection structure to the laterally displaced contact volume 112. To be more precise, charge carriers, or electrons travel through the vertical and lateral charge transport volumes 108 and 114 after having passed the transistor structure 72 or the diode 70.

The ESD-protection structure of FIG. 5 furthermore includes a second emitter volume 120, which extends from the first terminal border 106 to a second terminal border 122 in the direction opposite to the lateral direction 102. The second emitter volume 120 is of second conductivity type material, i.e. p-doped. Therefore, a p-n-p transistor structure 123 is formed in the lateral direction 102 from the base volume 60, the laterally neighbored collector volume 62, and the second emitter volume 120. Similar to the previously discussed case, the inherent resistivity of the lateral charge transport volume 114 leads to a field gradient in the lateral device direction 102, once a current flows through the lateral charge transport volume 114. When the current exceeds a predetermined threshold, the resistivity of the semiconductor material creates a field gradient, which is steep enough to cause a potential difference between the second emitter volume 120 and the collector volume 62 (the base of the lateral p-n-p transistor structure) high enough as to cause the lateral p-n-p structure to become conductive. That is, once a current exceeds a predetermined threshold, current transport through the structure will also spread out vertically to flow through the collector volume 62 in between the second emitter volume 120 and the base volume 60. Thus, higher currents can be transported by the electrostatic discharge protection structure as compared to a single vertical structure, since the volume used for charge transfer is further increased by the lateral p-n-p structure.

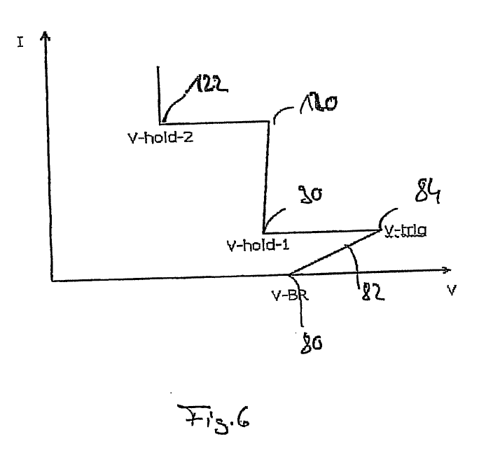

The electrostatic discharge protection device of FIG. 5 may show a voltage-current behavior as indicated in FIG. 6, where the voltage is plotted on the x-axis and the current is plotted on the y-axis. Up to the moment when the hold-voltage 90 is reached, the situation is equivalent to the one already discussed in FIG. 3. However, when the current further increases up to a second threshold current 120, the lateral p-n-p structure 123 becomes conductive and, for the same reasons as previously discussed for the vertical structure, the voltage required at the terminals to keep the structure conductive, decreases to a second hold-voltage 122, at the gain of being able to switch even higher currents without destroying the device.

To be more precise, with the lateral ESD-protection structure of FIG. 5, additional security may be gained, in that higher currents may be switched on occurrence of an ESD-event, without running in danger of destroying the ESD-protection device and, thus, having no further ESD-protection for the device to be protected.

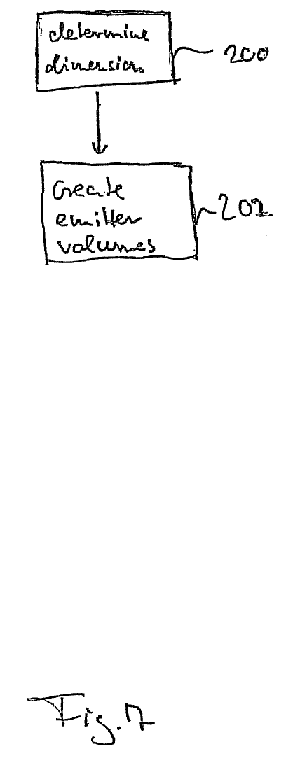

FIG. 7 illustrates an embodiment of a method for creating an emitter structure. In block 200, a lateral direction of an emitter volume of a first conductivity type material which is neighbored, in the lateral direction, by a semiconductor volume of a second conductivity type material, is determined to a predetermined lateral dimension such that space charges created by second conductivity type carriers laterally diffusing into the emitter volumes limit a maximum density of first conductivity tape carriers within the emitter volume by more than 20% as compared to an emitter volume of the same lateral dimension, which is not neighbored by a semiconductor volume of differing conductivity type. In block 202, emitter volumes extending the predetermined lateral dimension in the lateral direction are created within a volume of second conductivity type material to form an emitter structure, wherein the emitter volumes are physically separated from each other in the lateral direction.

Although most of the previously discussed embodiments relate to ESD-protection devices, or ESD-protection semiconductor structures, further embodiments of emitter structures may be applied to different semiconductor applications in which charge carriers are emitted or injected into neighboring semiconductor volumes. This could, for example, be applied within vertical FETs, such as JFETs, IGBTs or other vertical power transistors such as for example trench-transistors or the like. Furthermore, bipolar transistors using embodiments of emitter structures may be used.

The previous embodiments have mainly been described in terms of n-doped emitter volumes. It goes without saying that further embodiments may be implemented in a complementary technology, namely, using p-doped emitter volumes and n-doped semiconductor volumes laterally neighboring the emitter volumes.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit including a semiconductor emitter structure for emitting charge carriers of a first conductivity type into a base volume of a second conductivity type material neighbored to the emitter structure in a vertical direction, comprising:
multiple emitter volumes of the first conductivity type material having a predetermined lateral dimension in a lateral direction perpendicular to the vertical direction, the emitter volumes neighbored, in the lateral direction, by semiconductor volumes of the second conductivity type material, wherein
the predetermined lateral dimension is such that space charges created by second conductivity type carriers laterally diffusing into the emitter volumes from the semiconductor volumes limit a maximum density of the first conductivity type carriers within the emitter volumes by more than 20% as compared to emitter volumes of the same lateral dimension not neighbored by semiconductor volumes of the second conductivity type material.

2. The integrated circuit of claim 1, in which the predetermined lateral dimension is less than 1 μm.

3. The integrated circuit of claim 1, in which a first dopant concentration of the first conductivity type material of the emitter volumes and a second dopant concentration of the second conductivity type material of the semiconductor volumes is greater than 1*10¹⁹ 1/cm³ and smaller than 5*10²¹ 1/cm³.

4. The integrated circuit of claim 1, in which the multiple emitter volumes are geometrically shaped such that any dimension perpendicular to the vertical direction is below the predetermined lateral dimension.

5. The integrated circuit of claim 1, in which the emitter volumes are, in the lateral dimension, shaped rectangular and arranged such that each emitter volume is, at least at 3 side faces, enclosed by semiconductor volumes of the second conductivity type material.

6. A transistor structure, comprising:
multiple emitter volumes of a first conductivity type material having a predetermined lateral dimension in a lateral direction perpendicular to a vertical direction, the emitter volumes neighbored, in the lateral direction, by semiconductor volumes of a second conductivity type material, wherein the predetermined lateral dimension is such that space charges created by second conductivity type carriers laterally diffusing into the emitter volumes from the semiconductor volumes limit a maximum density of first conductivity type carriers within the emitter volumes by more than 20% as compared to emitter volumes of the same lateral dimension not neighbored by semiconductor volumes of the second conductivity type material;
a base volume of the second conductivity type material neighbored to the emitter structure in the vertical direction; and
a collector volume of the first conductivity type material neighbored to the base volume in the vertical direction.

7. The transistor structure of claim 6, further comprising:
a collector terminal connected to the collector volume;
a base terminal connected to the base volume, and
an emitter terminal, connected only to the multiple emitter volumes of the emitter structure.

8. An ESD-protection structure comprising:
an emitter structure comprising multiple emitter volumes of a first conductivity type material having a predetermined lateral dimension in a lateral direction perpendicular to a vertical direction, the emitter volumes neighbored, in the lateral direction, by semiconductor volumes of a second conductivity type material, wherein the predetermined lateral dimension is such that space charges created by second conductivity type carriers laterally diffusing into the emitter volumes from the semiconductor volumes limit a maximum density of first conductivity type carriers within the emitter volumes by more than 20% as compared to emitter volumes of the same lateral dimension not neighbored by semiconductor volumes of the second conductivity type material, wherein the multiple emitter volumes and the neighboring semiconductor volumes are electrically short circuited by a common terminal area;
a base volume of the second conductivity type material neighbored to the emitter structure in the vertical direction; and
a collector volume of the first conductivity type material neighbored to the base volume in the vertical direction.

9. The ESD-protection structure of claim 8, in which the predetermined lateral dimension is smaller than 1 μm.

10. The ESD protection structure of claim 8, in which dopant concentrations of the base volume and the collector volume are chosen such that an avalanche breakthrough between the two volumes occurs, when a predetermined trigger voltage is applied between the common terminal area and the collector volume.

11. The ESD-protection structure of claim 8, in which a first dopant concentration of the first conductivity type material of the emitter volumes and a second dopant concentration of the second conductivity type material of the semiconductor volumes is greater than 1*10¹⁹ 1/cm³ and smaller than 5*10²¹ 1/cm³.

12. The ESD-protection structure of claim 8, further comprising:
an anode terminal connected to the common terminal area; and
a cathode terminal connected to the collector volume.

13. An ESD-protection structure comprising:
an emitter structure comprising multiple emitter volumes of a first conductivity type material having a predetermined lateral dimension in a lateral direction perpendicular to a vertical direction, the emitter volumes neighbored, in the lateral direction, by semiconductor volumes of a second conductivity type material, wherein the predetermined lateral dimension is such that space charges created by second conductivity type carriers laterally diffusing into the emitter volumes from the semiconductor volumes limit a maximum density of first conductivity type carriers within the emitter volumes by more than 20% as compared to emitter volumes of the same lateral dimension not neighbored by semiconductor volumes of the second conductivity type material, wherein the multiple emitter volumes and the neighboring semiconductor volumes are electrically short circuited by a common terminal area;
a base volume of a second conductivity type material neighboring the emitter structure in the vertical direction and extending, in a lateral device direction perpendicular to the vertical direction, to a first semiconductor transition;
a collector volume of first conductivity type material neighboring the base volume in the vertical direction and extending, in the lateral device direction, from the first semiconductor transition to a terminal border; and
a vertical charge transport volume of first conductivity type material, extending, in the lateral device direction, from the terminal border to a lateral device border.

14. The ESD-protection structure of claim 13, further comprising:
a lateral charge transport volume of first conductivity material, neighboring the collector volume in the vertical direction and extending, in the lateral device direction, up to the lateral device border.

15. The ESD-protection structure of claim 13, further comprising:
a cathode terminal connected to the terminal volume; and
an anode terminal, connected to the common terminal area.

16. The ESD-protection structure of claim 13, further comprising:
a second emitter volume of second conductivity type material, the second emitter volume extending, in the direction opposite to the lateral direction, from the terminal border up to a second terminal border within the collector volume.

17. The ESD-protection structure of claim 16, in which the vertical charge transport volume and the second emitter volume are electrically short circuited to form a second common terminal area.

18. The ESD-protection structure of claim 17, further comprising:
a cathode terminal connected to the second common terminal area; and
an anode terminal connected to the common terminal area.

19. The ESD-protection device of claim 13, in which dopant concentrations of the base volume and the collector volume are chosen such that an avalanche breakthrough between the two volumes occurs at the border between the base volume and the collector volume when a predetermined trigger voltage is applied to the common terminal area and the vertical charge transport volume.

20. The ESD-protection device of claim 14, in which a dopant concentration of the lateral charge transport volume is such that a voltage gradient caused by the resistance of the lateral charge transport volume, triggers a current flow through the second emitter volume, when a predetermined current is exceeded within the lateral charge transport volume.

21. A method for creating a semiconductor device, comprising:
determining a lateral dimension in a lateral direction of an emitter volume of a first conductivity type material neighbored, in the lateral direction, by a semiconductor volume of second conductivity type material such that space charges created by second conductivity type carriers laterally diffusing into the emitter volumes from the semiconductor volumes limit a maximum density of first conductivity type carriers within the emitter volumes by more than 20% as compared to emitter volumes of the same lateral dimension not neighbored by semiconductor volumes of the second conductivity type material; and
creating, within a volume of second conductivity type material, multiple emitter volumes of first conductivity type material having the lateral dimension in the lateral direction, the multiple emitter volumes physically separated from each other in the lateral direction; and
short circuiting the volume of the second conductivity type material and the emitter volumes to form a common terminal.

22. The method of claim 21, further comprising:
creating a base volume of second conductivity type material, the base volume neighboring the emitter structure in the vertical direction and extending to the emitter volumes; and
creating a collector volume of first conductivity type material neighboring the base volume in the vertical direction.

23. The method of claim 21, further comprising:
creating an anode terminal of the device coupled to the common terminal; and
creating an cathode terminal of the device coupled to the collector volume.
